(19) United States
(12) Patent Application Publication
(10) Pub. No.: US 2005/0186757 A1
(43) Pub. Date: Aug. 25, 2005

(54) Method for lift off GaN pseudomask epitaxy layer using wafer bonding way

(75) Inventors: Yew-Chung Wu, Hsinchu (TW); Pei-Yen Lin, Hsinchu (TW); Hsien-Chih Peng, Hsinchu (TW)

Correspondence Address: TROXELL LAW OFFICE PLLC, SUITE 1404, 5205 LEESBURG PIKE, FALLS CHURCH, VA, 22041, US

(73) Assignee: National Chiao Tung University

(21) Appl. No.: 10/781,892

(22) Filed: Feb. 20, 2004

(51) Int. Cl. H01L 29/24

(52) U.S. Cl. 438/455

(57) ABSTRACT

The epitaxial lateral overgrowth (ELOG) GaN obtains the dangling structure by using wet etching and the transferred substrate to separate from the GaN epitaxy layer by using stress concentration of thermal expansion coefficient of the transferred substrate. It is useful to separate of the GaN epitaxy layer and transferred substrate by using anneal of wafer bonding. The present invention is to provide high selective etching rate, no damage to epitaxial film, low cost, and feasibility for larger commercial sizes. The wet etching method can not damage the separated epitaxial substrate, thus the substrate can be reused. There are various choices of handling substrate for bonding, not limited by the epitaxial method. When the epitaxial film is applied in devices, the low defect density of the epitaxial film can enhance the lifetime and efficiency of the devices. The addition of this improved fabrication process does not require expensive equipment. Moreover, it will reduce the production cost. The epitaxy substrate is a recyclable substrate after separation of wet etching method and the transferred epitaxy layer obtain low defect density, lifetime improvement and low cost.

### REFERENCE CITED

1. Y. Honda, et. al., “Selective area growth of GaN microstructures on patterned (111) and (001)
   Si substrates”, in Journal of Crystal Growth 230,
   p. 346-p. 350, 2001.
2. B. Beaumont, et. al., “Lateral overgrowth of GaN on patterned GaN/Sapphire substrate via selective metal organic vapour phase epitaxy: a route to produce self supported GaN substrates”, in Journal of Crystal Growth 189/190, p. 97-p. 102, 1998.
3. Jaime A. Freitas, et. al., “Optical and structural properties of lateral epitaxial overgrown GaN layers”, in Journal of Crystal Growth 189/190, p. 92-p. 96, 1998.
4. Shuji Nakamura, et. al., “Present status of InGaN/GaN/AIGaN-based laser diodes”,
   in Journal of Crystal Growth 189/190, p. 820-p. 825, 1998.
5. Kazumasa Hiramatsu, et. al., “Selective area growth and epitaxial lateral overgrowth of GaN by metalorganic vapor phase epitaxy and hydride vapor phase epitaxy”, in Materials Science and Engineering B59, p. 104-p. 111, 1999.
6. Tsvetanka S. Zheleva, et. al., “Lateral epitaxy and dislocation density reduction in selectively grown GaN structures”, in Journal of Crystal Growth 222, p. 706-p. 718, 2001.
7. Akira Sakai, et. al., “Defect structure in selectively grown GaN films with low threading dislocation density”, in American Institute of Physics, p. 2259-p. 2261, 1997.
8. Tsvetanka S. Zheleva, et. al., “Dislocation density reduction via lateral epitaxy in selectively grown GaN structures”, in American Institute of Physics, p. 2472-p. 2474, 1997.
9. W. S. Wong, et. al., “In xGa₁₋ₓN light emitting diodes on Si substrates fabricated by Pd—ln metal bonding and laser lift-off”, in Applied Physics Letters Volume 77, Number 18, p. 2822-p. 2824, 2000.
10. Mitsuru Funato, et. al., “Integration of GaN with Si using aAuGe-mediated wafer bonding technique”, in Applied Physics Letters Volume 77, Number 24, p. 3959-p. 3961, 2000.

### FIELD OF THE INVENTION

The present invention relates to a method for lift off Gallium Nitride (GaN) pseudomask epitaxy layer, more particularly, the invention relates to stress concentration of thermal expansion coefficient of said transferred substrate to separate from the transferred substrate.

### BACKGROUND OF THE INVENTION

According to the GaN technology, because GaN is difficult to grow bulk material, there dose not exist a GaN epitaxial substrate and GaN needs to epitaxy on the substrate made by other material. But, the epitaxial substrate that are usually used for growing GaN actually has some properties which are harmful to the device operation or commercial large-quantity production, such as insulation, hard, low thermal conductivity . . . etc., and all these cause the limitation of usages or efficiency of GaN.

Presently, the technologies for separating the GaN from the substrate include the laser lift off method and the smart cut method. But, both of them have limitations and disadvantages in applications. Generally, the laser lift off method is restricted by the smaller spot size of the laser beam and only can be used to separate a small portion of the GaN epitaxial layer at a time. Except the disadvantage described above, another drawback with using this method is that the energy of the laser beam is not easy to spread averagely and will then cause different decomposition rate and heat accumulation in different portions of the GaN epitaxy layer. Because it is hard to precisely control the heat transfer and decomposition at the GaN/substrate interface, partial surface of GaN layer therefore will become rough after being separated by this method. Furthermore, because of a thermal shock in the material, the quality of the GaN layer will be reduced, even more the GaN layer will be unusable. Consequently, the expensive laser equipment with smaller production efficiency is inappropriate for large-quantity production and also not suitable for saving the cost. As to the smart cut method, this method implants ions into the epitaxy layers before wafer bonding being progressed. Thus, the epitaxy layers are heated to vaporize ions to provide pressure for separating. However, the ion implantation process will destroy the crystal structure of the epitaxial layer, and the defect density which influences the device performance and the material quality will also be increased. Consequently, this method is not suitable to transfer semiconductor epitaxy layer for commercial purpose, either.

In addition, both of the methods have some other disadvantages that they are not appropriate for transferring the epitaxial layer in large area, the transferred epitaxial layer owns low quality, the epitaxial substrate can not be recycled, and the cost of the manufacturing process is much higher.

Because of the problems described above, the applicant keeps on carving unflaggingly to develop a “method for lift off GaN pseudomask epitaxy layer using wafer bonding way” through wholehearted experience and research.

### SUMMARY OF THE INVENTION

Therefore, the main purpose of this present invention relates to provide a method for lift off GaN pseudomask epitaxy layer using wafer bonding way, especially is a method of improving process of producing GaN epi-wafer, and also a great improvement in application and commercial mass production.

Another purpose of the present invention is to provide GaN epitaxy layer of high quality to transfer to selective substrate, wherein the GaN epitaxy layer of different substrates can provide various usage. As presented in the invention, we successfully developed a solution which overcome the GaN epi-wafer problems such as insulation, hard (Sapphire and SiC), low thermal conductivity . . . etc.

Another purpose of this present invention is to provide a new substrate transfer technology to substitute for laser lift-off or smart cut, which is suitable to large sizes area and commercial mass production.

The last purpose of this present invention is to provide GaN epitaxy layer formed by Epitaxial Lateral Overgrowth (ELOG) GaN method using wafer bonding way.

To achieve above purpose, this present invention relates to a method for lift off GaN pseudomask epitaxy layer using wafer bonding way, characterized in that, a low temperature buffer layer deposited on a substrate and a mask layer deposited on the low temperature buffer layer and continue by using a pattern etched on the mask layer, subsequently, ELOG GaN processed to the etched mask layer to forming a GaN epitaxy layer, and a transferred substrate bonding with GaN epitaxy layer by using wafer bonding way; finally, Immerse the substrate, thed low temperature buffer layer, the mask layer, the GaN epitaxy layer and the transferred substrate in etching solution and then the substrate, the low temperature buffer layer and the GaN epitaxy layer by using stress concentration of thermal expansion coefficient of said transferred substrate to separate from the transferred substrate.

### BRIEF DESCRIPTION OF THE DRAWINGS

The present invention will be better understood from the following detailed description of preferred embodiments of the invention, taken in conjunction with the accompanying drawings, in which

FIG. 1 is a view showing step (1) according to the present invention;

FIG. 2 is a view showing steps (2) and (3) according to the present invention;

FIG. 3 is a view showing step (4) according to the present invention;

FIG. 4 is a view showing step (5) according to the present invention;

FIG. 5 is a view showing step (6) before separation according to the present invention; and

FIG. 6 is a view showing step (6) after separation according to the present invention.

### DESCRIPTION OF THE PREFERRED EMBODIMENTS

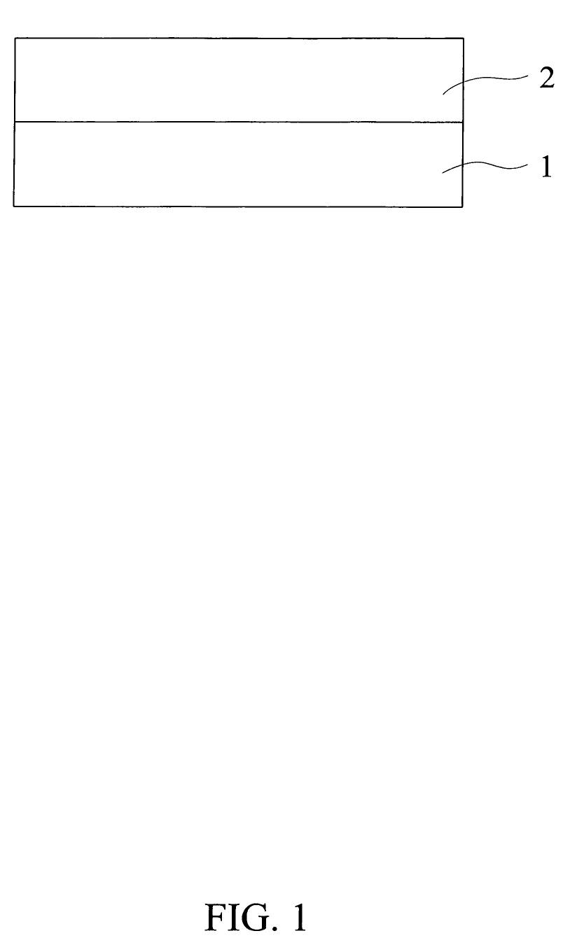

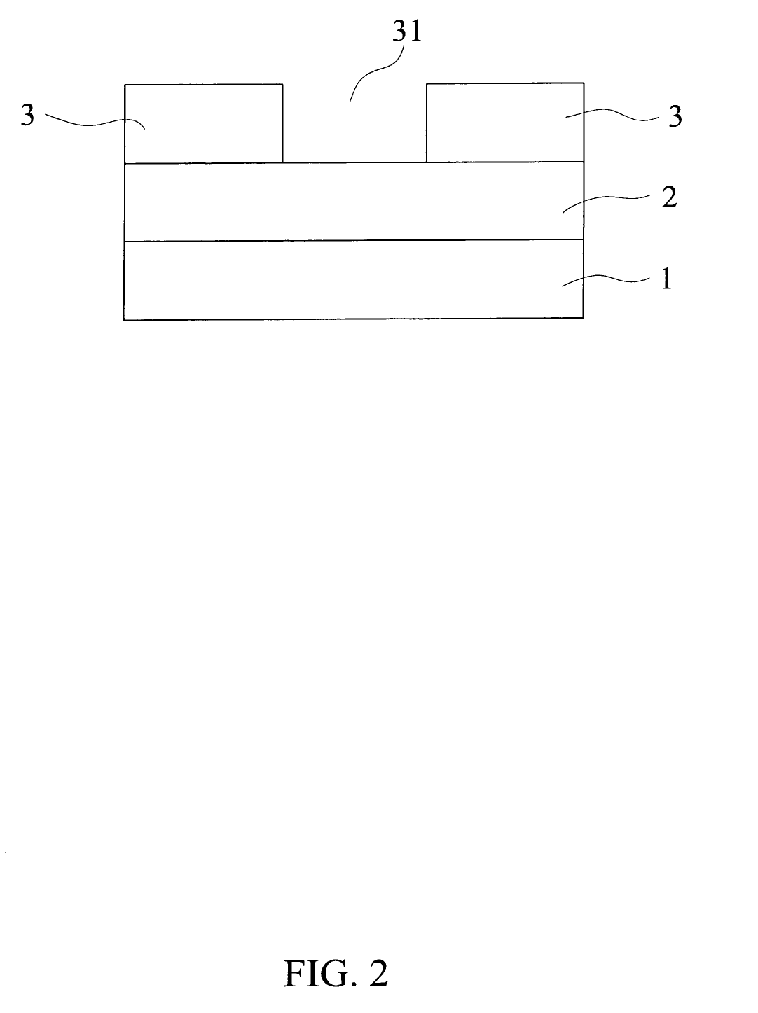

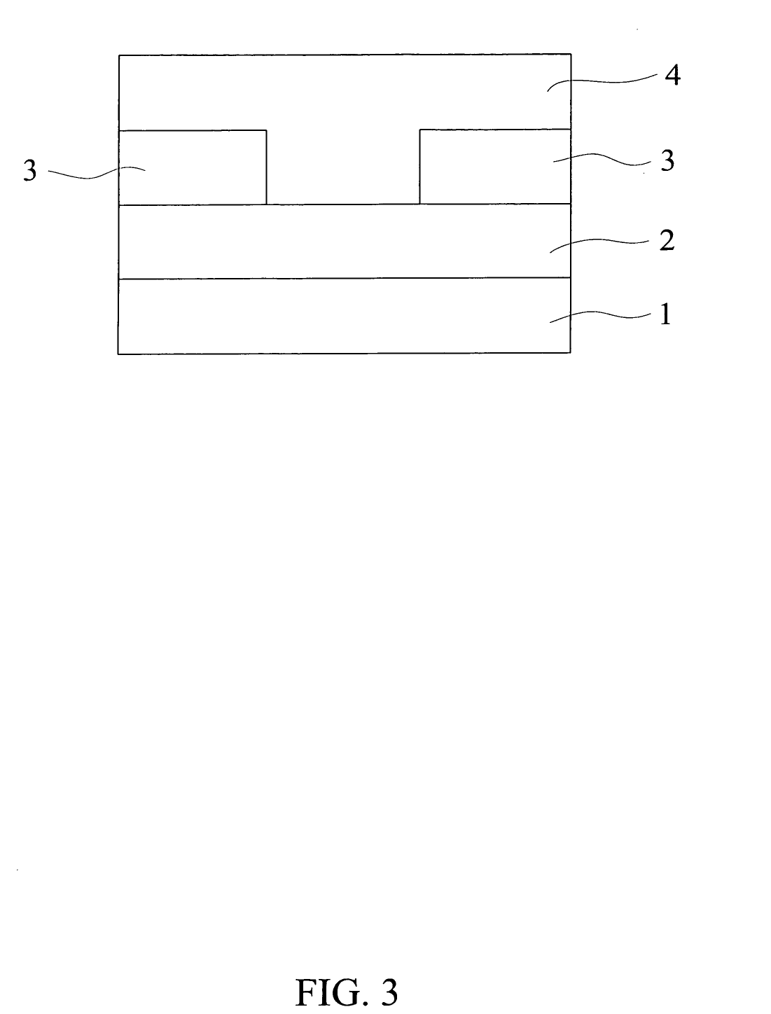

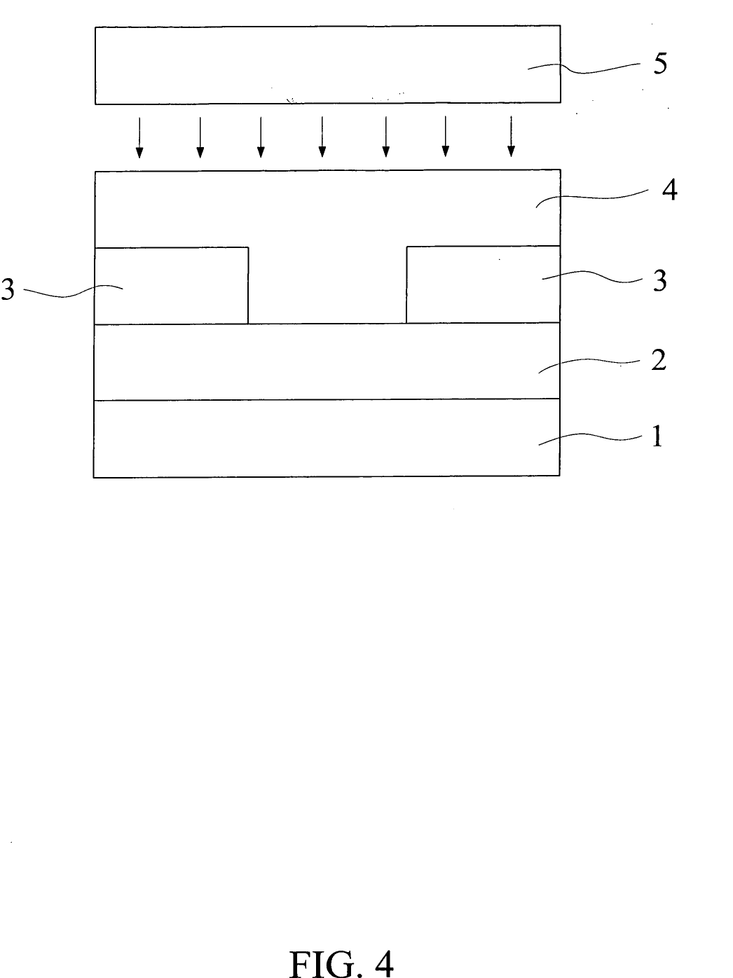

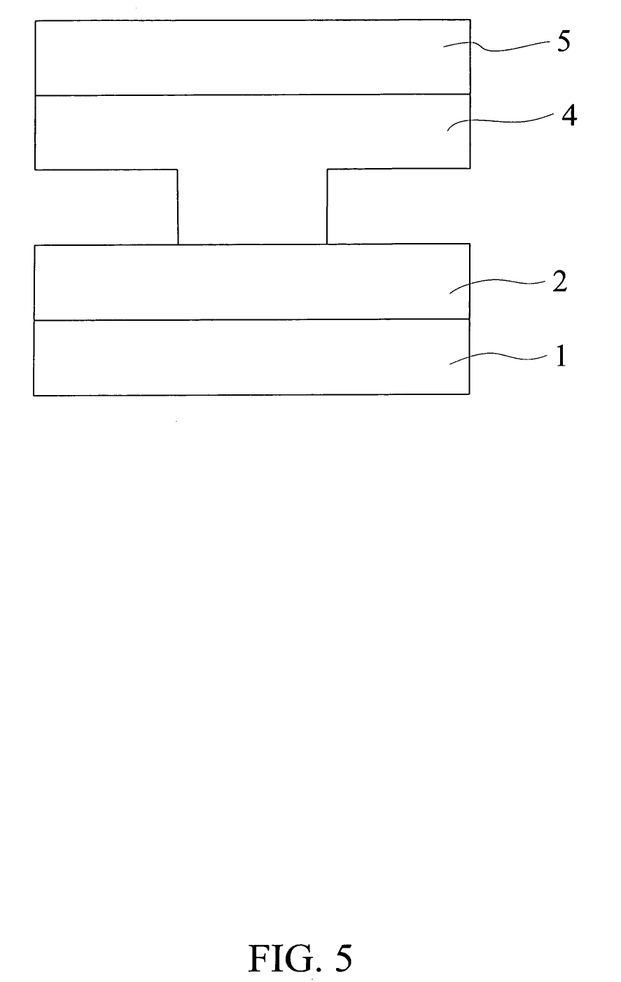

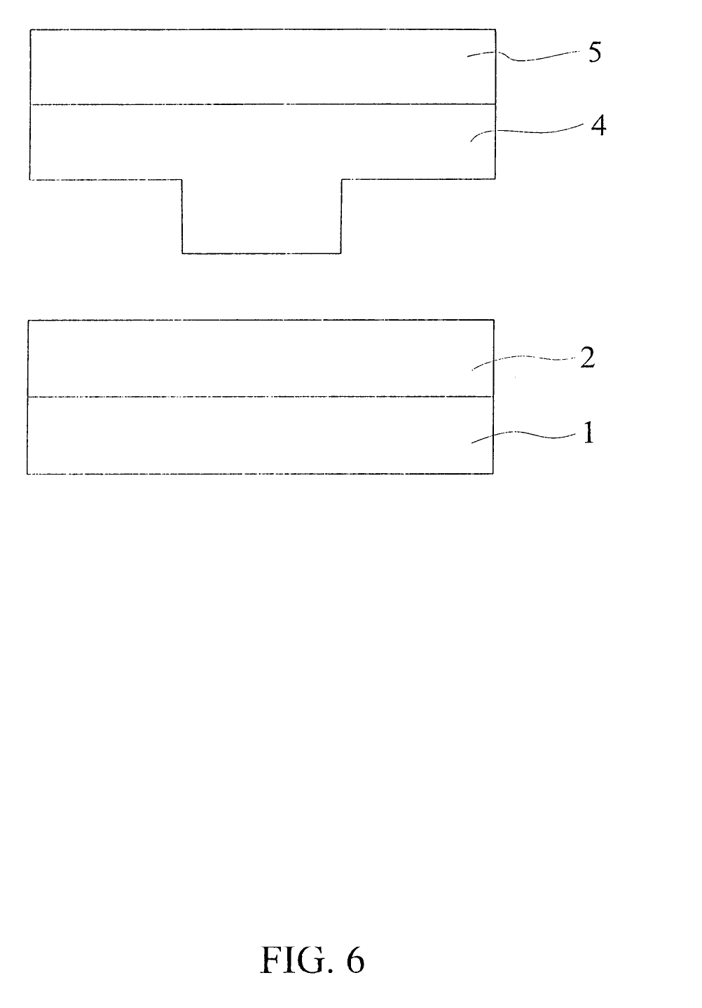

The following descriptions of the preferred embodiments are provided to understand the procedure and the methods of the present invention. Please refer to FIG. 1 to FIG. 6. FIG. 1 is a view showing step (1) according to the present invention; FIG. 2 is a view showing steps (2) and (3) according to the present invention; FIG. 3 is a view showing step (4) according to the present invention; FIG. 4 is a view showing step (5) according to the present invention; FIG. 5 is a view showing step (6) before separation according to the present invention; and FIG. 6 is a view showing step (6) after separation according to the present invention. The above-identified figures show a method for lift off GaN pseudomaske epitaxy layer using wafer bonding way comprising the steps of:

1. Deposit the low temperature buffer layer 2 on the substrate 1. Material of substrate 1 is selected from the group consisting of Sapphire, Silicon Carbide (SiC) and Silicon (Si). The depositing procedure of the low temperature buffer layer 2 is to deposit the low temperature GaN or Aluminum Nitride (AIN) with a thickness in the range of 200-500 microns by using a temperature of 600-700 degrees Celsius on the substrate 1, and then deposit 1.5 micron-thick GaN on the GaN or Aluminum Nitride (AIN) film by temperature in the range of 1000-1100 degrees Celsius.

2. Deposit the mask layer 3 on said low temperature buffer layer 2 of step (1). The mask layer 3 is a metal or ceramic, that is selected from the group consisting of SiO₂, Si₃N₄ and W.

3. Etch the pattern 31 on the mask layer 3 of step (2). The pattern 31 is selected from the group consisting of dot pattern and line pattern shown in FIG. 2;

4. Process ELOG GaN on the etched mask layer 3 of step (3) obtaining a smoothed surface having a mirror surface to form the GaN epitaxy layer 4 shown in FIG. 3. The GaN epitaxy layer process ELOG on the mask layer 3 by temperature in the range of 1000-1100 degrees Celsius.

5. Obtain a transferred substrate 5 after clean process by using wafer bonding to connect with said GaN epitaxy layer 4. The transferred substrate can be a Silicon (Si). The wafer bonding is carried out using a temperature depending on material of the transferred substrate 5 shown in FIG. 4.

6. Immersing the substrate 1, the low temperature buffer layer 2, the mask layer 3, the GaN epitaxy layer 4, the transferred substrate 5 in etching solution and then the substrate 1, the low temperature buffer layer 2, the GaN epitaxy layer 4 by using stress concentration of thermal expansion coefficient of the transferred substrate 5 to separate from said transferred substrate shown in FIG. 5 and FIG. 6. Therefore, according to the above steps carry out the method for lift off GaN pseudomask epitaxy layer using wafer bonding way.

The present invention discloses using GaN from selective area growth, and processing epitaxy lateral overgrowth to related materials. Because of the chemical erosion of mask using ELOG is different to GaN. Therefore, the separation of the GaN epitaxy layer 4 and the epitaxy substrate 1 is carried out using wafer bonding and chemical selective etching.

The present invention separates the substrate 1 to overcome the problems of conventional method which include damage of GaN epitaxy layer 4, high cost, not suitable for large commercial size by using chemical reaction principle.

The present approach differs from conventional methods in that effects comprising:

For the low temperature buffer layer 2 and separated substrate 1, that can not be destroyed in the process of separation and be recyclable to reduce productive cost.

The wafer bonding way of the present invention not only provides GaN epitaxy layer 4 a new supporting substrate, but also the anneal process obtains the stress concentration of thermal expansion coefficient of substrate, that is useful for selective chemical etching in the process of substrate separation.

According to the present invention, The GaN epitaxy layer 4 transfer to various types of substrate, that provides various applications. Therefore, the present invention overcome the conventional problems of substrate which include nonconductor, not easy incision, not easy heat dissipating etc.

The present invention may be embodied in other specific forms without departing from the spirit of the essential attributes thereof; therefore, the illustrated embodiment should be considered in all respects as illustrative and not restrictive, reference being made to the appended claims rather than to the foregoing description to indicate the scope of the invention.

1. A method for lift off Gallium Nitride (GaN) pseudomaske epitaxy layer using wafer bonding way comprising the steps of:
(1) Depositing a low temperature buffer layer on a substrate;
(2) Depositing a mask layer on said low temperature buffer layer of step (1)
(3) Etching a pattern on said mask layer of step (2)
(4) Processing epitaxy lateral overgrowth (ELOG) GaN on etched mask layer of step (3) obtaining a smoothed surface to form a GaN epitaxy layer;
(5) obtaining a transferred substrate after clean process by using wafer bonding to connect with said GaN epitaxy layer; and
(6) Immersing said substrate, said low temperature buffer layer, said mask layer, said GaN epitaxy layer and said transferred substrate in etching solution and then said substrate, said low temperature buffer layer and said GaN epitaxy layer by using stress concentration of thermal expansion coefficient of said transferred substrate to separate from said transferred substrate.

2. The method according to claim 1, wherein material of said substrate is selected from the group consisting of Sapphire, Silicon Carbide (SiC) and Silicon (Si).

3. The method according to claim 1, wherein said low temperature buffer layer comprises depositing GaN or Aluminum Nitride (AlN) with a thickness in the range of 200-500 microns by a temperature of 600-700 degrees Celsius and then depositing 1.5 micron-thick GaN by temperature in the range of 1000-1100 degrees Celsius.

4. The method according to claim 1, wherein said mask layer is selected from the group consisting of SiO₂, Si₃N₄ and tungsten (W).

5. The method according to claim 1, wherein said pattern is selected from the group consisting of a dot pattern and line pattern.

6. The method according to claim 1, wherein said GaN epitaxy layer comprises epitaxy lateral overgrowth (ELOG) on mask layer with the range of 1000-1100 degrees Celsius.

7. The method according to claim 1, wherein said transferred substrate is a Silicon (Si).

8. The method according to claim 1, wherein said wafer bonding of step (5) is carried out using a temperature depending on said transferred substrate.

9. The method according to claim 1, wherein selecting of said etching solution of step (6) is carried out depending on said mask layer and said transferred substrate.
